(19) United States
(12) Patent Application Publication
(10) Pub. No.: US 2009/0301748 A1
(43) Pub. Date: Dec. 10, 2009

(54) HOUSING, ELECTRONIC DEVICE USING THE HOUSING, AND MANUFACTURING METHOD THEREOF

(75) Inventors: CHE-YUAN HSU, Shindian (TW); FU-KENG YANG, Shindian (TW); CHENG-WEN SU, Shindian (TW); YI-QIANG XU, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/475,670

(22) Filed: Jun. 1, 2009

(30) Foreign Application Priority Data
Jun. 6, 2008 (CN) 200810302060.3

(51) Int. Cl. H05K 5/00; B29C 45/16

(52) U.S. Cl. 174/50; 264/259

(57) ABSTRACT

A housing includes a thin film comprising transparent plastic and color particles, a protecting film attached to the thin film; and a substrate attached to the protecting film. A method for manufacturing the housing and an electronic device using the housing are also disclosed.

### BACKGROUND

1. Technical Field

The present disclosure generally relates to housings, and particularly, to a housing for an electronic device, and a method for making the housing.

2. Description of Related Art

Portable electronic device such as mobile phones, laptops and personal digital assistants (PDAs) are widely used. Most housings of portable electronic devices are made by in mold labeling (IML). A typical housing includes a transparent plastic film, an ink coating attached to an inner surface of the transparent plastic film, a protecting film attached to the ink coating, and a substrate moldingly attached to the protecting film by an insert molding process. The ink coating is attached to the transparent plastic film by a printing process, and is very expensive, thereby increasing cost.

Therefore, there is room for improvement within the art.

### BRIEF DESCRIPTION OF THE DRAWINGS

Many aspects of the housing for an electronic device can be better understood with reference to the following drawings. The components in the drawings are not necessarily drawn to scale, the emphasis instead being placed upon clearly illustrating the principles of the housing for an electronic device. Moreover, in the drawings like reference numerals designate corresponding parts throughout the several views.

FIG. 1 is a cross sectional view of a housing.

FIG. 2 is a cross sectional view of a first thin film and a second thin film laminated in rollers to make the housing.

### DETAILED DESCRIPTION OF THE DISCLOSURE

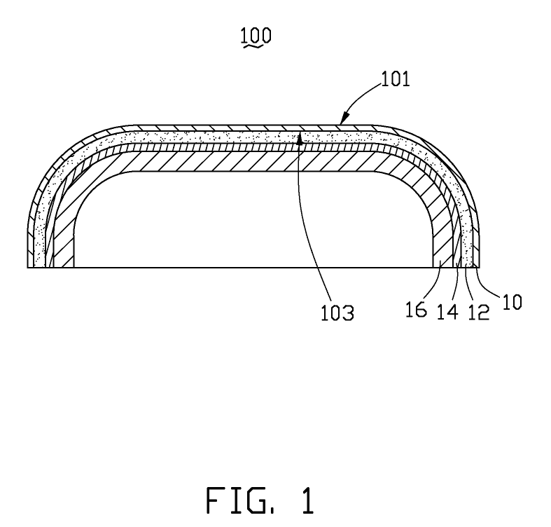

Referring to FIG. 1, an exemplary housing 100 includes a first thin film 10, a second thin film 12 attached to the first thin film 10, a protecting film 14 attached to the second thin film 12, and a substrate 16 attached to the protecting film 14.

The first thin film 10 is transparent plastic selected from a group consisting of polypropylene (PP) and polyamide (PA). The first thin film 10 includes an outer surface 101 and an inner surface 103 opposite to the outer surface 101.

The second thin film 12 includes transparent plastic and color particles. The transparent plastic is selected from a group consisting of polycarbonate (PC), polyethylene terephthalate (PET), and polymethylmethacrylate (PMMA). The color particles are color master batches. The color master batches are uniformly distributed in the second thin film 12, thereby decorating the second thin film 12.

The protecting film 14 is attached to the second thin film 12 using adhesive, and configured for protecting the second thin film 12.

The substrate 16 is made of plastic selected from a group consisting of polyethylene (PE), acrylonitrile-butadiene-styrene (ABS), polymethylmethacrylate (PMMA), and polyethylene terephthalate (PET).

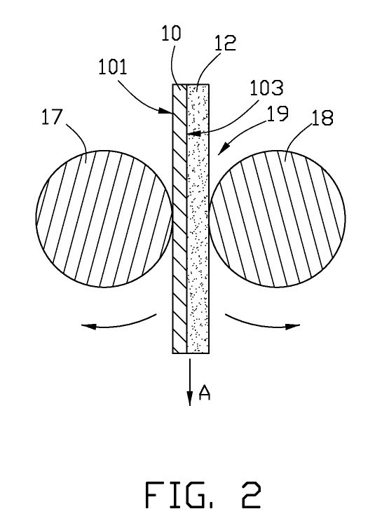

Referring to FIG. 2, during manufacturing the housing 100, the first thin film 10 and the second thin film 12 are firstly provided.

A first cylindrical roller 17 and a second cylindrical roller 18 are provided and rotate in opposite directions at a same level. According to the exemplary embodiment, the first cylindrical roller 17 rotates in a clockwise direction, and the second cylindrical roller 18 rotates in a counterclockwise direction.

The first cylindrical roller 17 and the second cylindrical roller 18 define a gap 19 therebetween. The width of the gap 19 is slightly smaller than the thickness of the first thin film 10 and the second thin film 12. The first thin film 10 and the second thin film 12 are inserted into the gap 19, and are moved along direction of arrow A by the first cylindrical roller 17 and the second cylindrical roller 18. Once the thin film 10 has completely passed through the gap 19, the second thin film 12 is attached to the inner surface 103 of the first thin film 10.

The protecting film 14 is attached to the second thin film 12 using adhesive, and configured for protecting the second thin film 12.

The first thin film 10 and the second thin film 12 are formed in accordance with a predetermined shape of the housing 100 shown in FIG. 1.

An injection mold is provided. The first thin film 10 and the second thin film 12 are placed into the injection mold. A substrate 16 is attached to the protecting film 14 by an injection molding process.

The color master batches are distributed in the second thin film 12, thereby decorating the second thin film 12, thereby omitting a printing process and reducing the cost.

It should be also understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing, comprising:
a thin film comprising transparent plastic and color particles;
a protecting film attached to the thin film; and
a substrate attached to the protecting film.

2. The housing as claimed in claim 1, wherein the thin film includes a first thin film and a second thin film opposite to the first thin film, the second thin film includes transparent plastic and color particles.

3. The housing as claimed in claim 2, wherein the transparent plastic is selected from a group consisting of polycarbonate, polyethylene terephthalate, and polymethylmethacrylate.

4. The housing as claimed in claim 2, wherein the first thin film is selected from a group consisting of polypropylene and polyamide.

5. The housing as claimed in claim 1, wherein the substrate is selected from a group consisting of polyethylene, acrylonitrile-butadiene-styrene, polymethylmethacrylate, and polyethylene terephthalate.

6. An electronic device, comprising:
a housing, comprising:
a thin film comprising transparent plastic and color particles;
a protecting film attached to the thin film; and
a substrate attached to the protecting film.

7. The electronic device as claimed in claim 6, wherein thin film includes a first thin film and a second thin film opposite to the first thin film, the second thin film includes transparent plastic and color particles.

8. The electronic device as claimed in claim 7, wherein the transparent plastic is selected from a group consisting of polycarbonate, polyethylene terephthalate, and polymethylmethacrylate.

9. The electronic device as claimed in claim 7, wherein the first thin film is selected from a group consisting of polypropylene and polyamide.

10. The electronic device as claimed in claim 6, wherein the substrate is selected from a group consisting of polyethylene, acrylonitrile-butadiene-styrene, polymethylmethacrylate, and polyethylene terephthalate.

11. A method for manufacturing a housing, comprising:
providing a first thin film;
providing a second thin film comprising transparent plastic and color particles;
providing a first cylindrical roller and a second cylindrical roller rotating at a direction inverse to the first cylindrical roller, the first cylindrical roller and the second cylindrical roller defining a gap therebetween;
placing the first thin film and the second thin film into the gap, the first thin film attached to the second thin film;
providing a protecting film attached to the second thin film; and
providing a substrate attached to the protecting film.

12. The method for manufacturing a housing as claimed in claim 11, wherein the first thin film is selected from a group consisting of polypropylene, and polyamide.

13. The method as claimed in claim 11, wherein the transparent plastic is selected from a group consisting of polycarbonate, polyethylene terephthalate, and polymethylmethacrylate.

14. The method as claimed in claim 13, wherein the substrate is made of plastic and attached to the protecting film by an injection molding process.

15. The method as claimed in claim 14, wherein the first thin film, the second thin film and the protecting film are formed a predetermined shape of the housing before injecting the substrate to the protecting film.
